(19) United States
(12) Patent Application Publication
(10) Pub. No.: US 2016/0204303 A1
(43) Pub. Date: Jul. 14, 2016

(54) USING AN ACTIVE SOLDER TO COUPLE A METALLIC ARTICLE TO A PHOTOVOLTAIC CELL

(71) Applicant: GTAT CORPORATION, Merrimack, NH (US)

(72) Inventors: Gopal Prabhu, San Jose, CA (US); Dong Xu, Fremont, CA (US); Venkatesan Murali, San Jose, CA (US)

(21) Appl. No.: 14/912,478

(22) PCT Filed: Jul. 26, 2014
(86) PCT No.: PCT/US14/48322

§ 371 Date: Feb. 17, 2016

Related U.S. Application Data
(60) Provisional application No. 61/868,436, filed on Aug. 21, 2013.

(51) Int. Cl. H01L 31/18; H01L 31/0475; H01L 31/02

(52) U.S. Cl. CPC H01L 31/1876; H01L 31/0201; H01L 31/0475

(57) ABSTRACT

Methods include providing a metallic article that is configured to serve as an electrical conduit within a photovoltaic cell. The processes further include providing a semiconductor substrate that includes a coating at a top surface of the semiconductor substrate, where the coating is a dielectric anti-reflective coating, a transparent conductive oxide or an amorphous silicon. The metallic article is coupled to the top surface of the semiconductor substrate, including soldering a first surface of the metallic article to the top surface of the semiconductor substrate using an active solder.

### RELATED APPLICATIONS

This application claims priority to U.S. Provisional Patent Application No. 61/868,436, filed on Aug. 21, 2013 and entitled “Using An Active Solder To Couple A Metallic Article To A Photovoltaic Cell,” which is hereby incorporated by reference for all purposes.

### BACKGROUND

A solar cell is a device that converts photons into electrical energy. The electrical energy produced by the cell is collected through electrical contacts coupled to the semiconductor material, and is routed through interconnections with other photovoltaic cells in a module. The “standard cell” has a semiconductor material, used to absorb the incoming solar energy and convert it to electrical energy, placed below an anti-reflective coating (ARC) layer, and above a metal backsheet.

The process in which an electrical conduit carrying current from the semiconductor substrate is attached to the semiconductor substrate or ARC layer is a critical aspect of ensuring that the resulting solar cell meets both performance and reliability requirements. Conventional methods of attachment involve using a solder to attach the electrical conduit to metallic portions of the semiconductor substrate. The conventional methods require using a flux to remove native oxide and using additional force or pressure to create a mechanical bond in conjunction with a chemical reaction of the solder.

### SUMMARY

Methods include providing a metallic article that is configured to serve as an electrical conduit within a photovoltaic cell. The processes further include providing a semiconductor substrate that includes a coating at a top surface of the semiconductor substrate, where the coating is a dielectric anti-reflective coating, a transparent conductive oxide or an amorphous silicon. The metallic article is coupled to the top surface of the semiconductor substrate, including soldering a first surface of the metallic article to the top surface of the semiconductor substrate using an active solder.

### BRIEF DESCRIPTION OF DRAWINGS

Each of the aspects and embodiments of the invention described herein can be used alone or in combination with one another. The aspects and embodiments will now be described with reference to the attached drawings.

FIG. 1A is a perspective view of a conventional solar cell.

FIG. 1B is a cross-sectional view of a conventional application of flux to a metallic article for a photovoltaic cell.

FIG. 2 is a perspective view of an exemplary attachment of an electrical conduit metallic article to a semiconductor surface according to an embodiment.

FIG. 3A-3B are top views of metallic articles used in embodiments.

FIG. 3C is a cross-sectional view of section B-B of FIG. 3B.

FIG. 4A is a perspective view of an embodiment of an electroplating mandrel for preparing metallic articles.

FIGS. 4B-4D are simplified cross-sectional views of exemplary stages in producing a metal article using a mandrel.

FIG. 5 is a perspective view of an ultrasonic soldering tool according to an embodiment.

FIG. 6 is a perspective view of an ultrasonic soldering setup according to an embodiment.

FIG. 7 is a flow diagram of an exemplary method according to an embodiment.

FIG. 8 is a flow diagram of an exemplary method according to another embodiment.

### DETAILED DESCRIPTION

Methods for attaching an electrical component for a photovoltaic cell are disclosed that simplify and reduce the overall cost of an attachment process while increasing the reliability and performance of solar cells and modules. The processes improve the bonding of an electrical component for a photovoltaic cell, while reducing the need for a flux to remove native oxides.

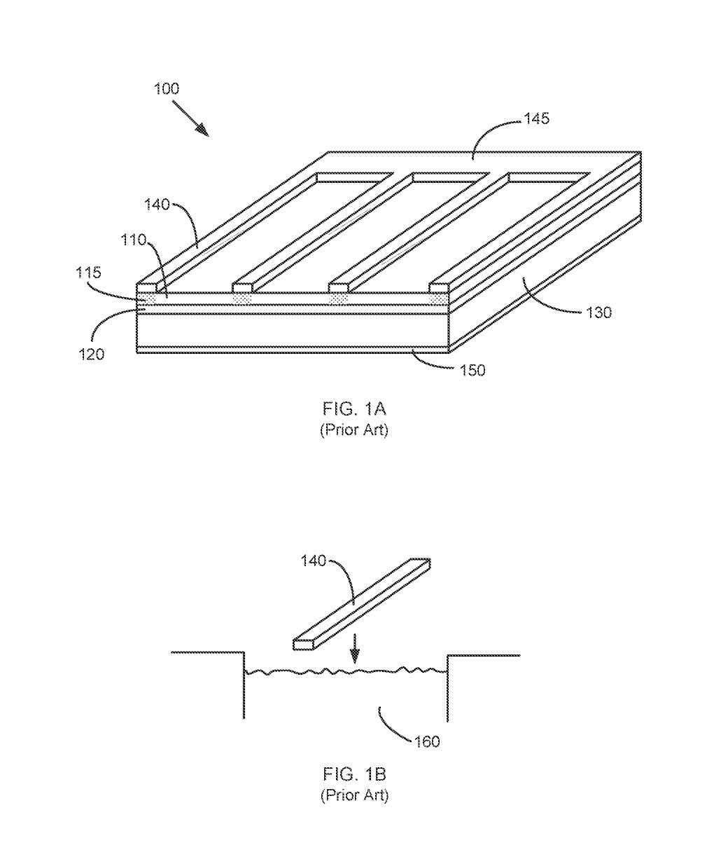

FIG. 1A is a simplified perspective view of a conventional solar cell 300 which includes an anti-reflective coating (ARC) layer 110, an emitter 120, a base 330, front contacts 140, and a rear contact layer 150. ARC layer 110 may be, for example, silicon nitride. Emitter 320 and base 130 are semiconductor materials that are doped in opposite polarities, and may be referred to together as an active region of a solar cell. Front contacts 140 may be, for example, a metallized region fabricated using a silver fire-through paste. The silver paste is typically fired through anti-reflective coating layer 510 in order to make electrical contact with the active region via fire-through regions 115, shown as dotted-pattern areas. Incident light enters the solar cell 100 through ARC layer 110, which causes a photocurrent to be created at the junction of the emitter 120 and base 130. it can be seen that shading caused by front contacts 140 will affect the efficiency of the cell 100. The produced electrical current is collected through an electrical circuit connected to front contacts 140 and rear contact 150. A bus bar 145 may connect the front contacts 140, which are shown as finger elements. The bus bar 145 collects the current from front contacts 140. The bus bar 145 may also be used to provide interconnection between other solar cells by soldering a metal ribbon (not shown) to the bus bar 145, stringing the metal ribbon to a nearby (e.g., adjacent) cell, and soldering the ribbon to the nearby cell. The assembly of front contacts 140 and bus bar 145 may also be referred to as a metallization layer. In other types of solar cells, a transparent conductive oxide (TCO) layer may replace or be placed over ARC layer 110 to collect electrical current. In a TCO type of cell, metallization in the form of for example, front contacts 140 and bus bar 145 would be fabricated onto the TCO layer, without the need for firing through, to collect current from the TCO solar cell. For example, in heterojunction cells, the layer 110 is a TCO layer, and coating layer 120 may be an amorphous silicon. In some TCO solar cells, the front, contacts 140 and 145 (and consequently fire-through regions 115) need not be present.

In other conventional methods, front contacts 140 and bus bar 145, may be metallic components attached to the semiconductor materials and/or ARC layer 110. Conventional attachment methods involve coating the metallic components with a solder and then melting the solder to form an intermetallic joint with the metallized portions of semiconductor materials and/or metallized portions of ARC layer 110. Metallization of solar cells typically involves screen printing a silver paste in the desired pattern of the electrical contacts to be connected to the cell. In FIG. 1A, the front contacts 140 are configured in a linear pattern of parallel segments and the bus bar 145 is perpendicular to the front contacts 140. The intermetallic joint is typically joined at these metallized portions 115 underneath front contacts 140 and bus bar 145. Conventionally soldered front contacts are relatively flat and wide to provide the needed electrical conductivity for current collection. These flat and wide fingers can be easily soldered to the cell, with sufficient mechanical strength provided by the bonding area of the fingers to the metallized areas of the cell. However, for contacts that are reduced in size, such as to minimize shading on the light incident surface of the photo voltaic cell, the decreased bonding area will affect the mechanical strength between the contacts and cell.

Conventional methods of attaching metallic components use a flux to remove native oxides. FIG. 1B is a cross-sectional view of a conventional application of flux 160 to a metallic article, such as the front contact 140 and/or bus bar 145, for a photovoltaic cell. The flux 160 is shown in a molten form into which the front contact 140 is conventionally dipped to remove oxide prior to soldering. The flux 160 is a chemical agent whose primary purpose is to prevent oxidation of the front contact 140 through reduction reactions. The flux 160 can also be used for wetting, i.e., priming an outer surface of the front contact 140 for soldering, as solder may flow more easily on flux than on the front contact 140 thus allowing for a more even application of the solder to the front contact 140. Using the flux 160, however, can have certain drawbacks. For example, fluxes can be chemically aggressive, which may degrade components and affect performance of the solar cell over time. Most fluxes require cleaning after soldering, which can add cost. For no-clean fluxes, chemical residuals from the flux remain trapped in the cell, which may cause damage of the cell. Thus, processes for attaching metallic articles to the semiconductor substrate without having to use flux are desired and are disclosed herein.

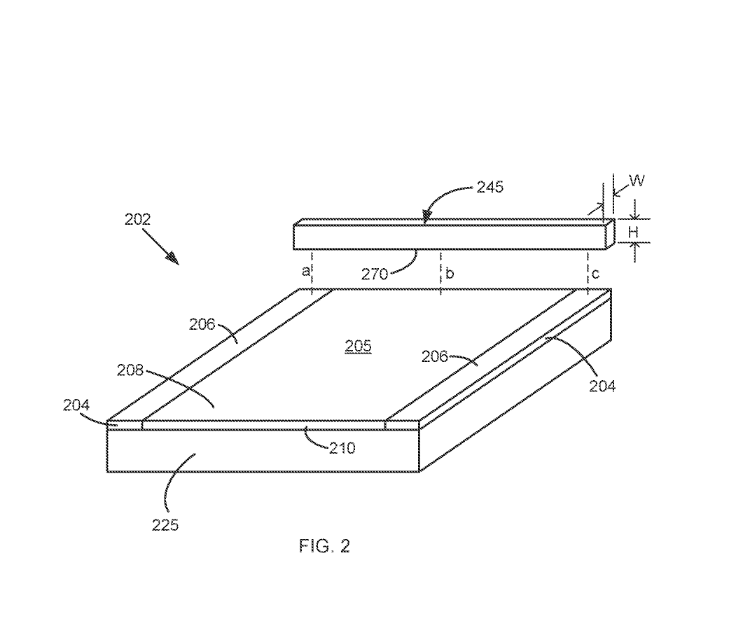

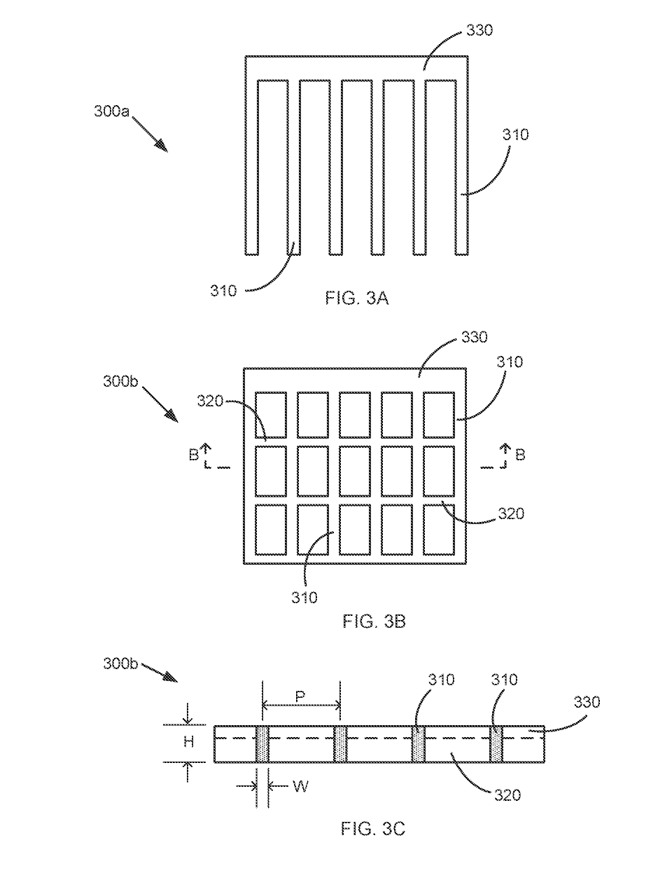

FIG. 2 is a perspective view of an exemplary attachment of an electrical conduit (e.g., metallic article 245) to a portion of a semiconductor 202 according to an embodiment. The metallic article 245 can be fabricated, for example, from copper for increased conductivity and can also have a nickel coating to resist corrosion. The metallic article 245 can be an elongated element having an aspect ratio greater than 1 so as to minimize shading of the solar cell, the aspect ratio being a ratio of a height “H” of the elongated element to a width “W” of the elongated element, as explained in more detail in Babayan et al., related application U.S. patent application Ser. No. 13/798,123, entitled “Free-Standing Metallic Article for Semiconductors” and filed on Mar. 13, 2013, which is owned by the assignee of the present application and is hereby incorporated by reference. For example, the elongated element may be fingers 310 and 320, or frame element 330 as shown in FIGS. 3A-3C and described further below. Alternatively, the metallic article 245 can include a grid pattern with height-to-width aspect ratios that minimize shading for the photovoltaic cell, as explained in more detail in Babayan et al., and shown in FIG. 3B, which is described further below. The metallic article 245 may be electroformed, as explained in more detail in Babayan et al.

In FIG. 3C, fingers 310 in this embodiment are shown as having aspect ratios greater than 1, such as about 1 to about 5, and such as approximately 2 in this figure. Having a cross-sectional height greater than the width reduces the shading impact of metal layer 300b on a photovoltaic cell. In various embodiments, only a portion of the fingers 310 and 320 may have an aspect ratio greater than 1, or a majority of the fingers 310 and 320 may have an aspect ratio greater than 1, or all of the fingers 310 and 320 may have an aspect ratio greater than 1. Height ‘H’ of fingers 310 may range from, for example, about 5 microns to about 5 mm, such as about 5 microns to about 200 microns, or about 10 microns to about 300 microns. Width ‘W’ of fingers 310 may range from, for example, about 10 microns to about 5 mm, such as about 10 microns to about 150 microns. The distance between parallel fingers 310 has a pitch ‘P’, measured between the centerline of each finger. In some embodiments the pitch may range, for example, between about 1 mm and about 25 mm. In various embodiments, the fingers 310 and 320 may have different widths, heights and pitches as each other, or may have some characteristics that are the same, or may have all the characteristics the same. The values may be chosen according to factors such as the size of the photovoltaic cell, the shading amount for a desired efficiency, or whether the metallic article is to be coupled to the front or rear of the cell. In some embodiments, fingers 310 may have a pitch between about 0.5 mm and about 6 mm and fingers 320 may have a pitch between about 1.5 mm and about 25 mm. Fingers 310 and 320 are formed in mandrels having grooves that are substantially the same shape and spacing as fingers 310 and 320. Frame element 330 may have the same height as the fingers 310 and 320, or may be a thinner piece as indicated by the dashed line in FIG. 3C. In other embodiments, frame element 330 may be formed on or above finger elements 310 and 320.

Returning to FIG. 2, an ARC layer 210 is provided at the top surface of an active region 225. Electrical contact can be made to the active region 225 with a conductive layer 204, such as a metal paste that is heated such that the paste fires through and diffuses through the ARC layer 210 and contacts the surface of the active region 225. The conductive layer 204 can be patterned into a set of fingers and bus bars which will then be soldered with ribbon to other cells to create a module. In another aspect, a solar cell can have a semiconductor material sandwiched between transparent conductive oxide layers (TCO's), which are then coated with a final layer of conductive paste that is also configured in a finger/bus bar pattern. In both these types of cells, the conducive layer 204—such as silver paste, PVD nickel, or PVD ITO—works to enable current flow in the horizontal direction (parallel to the cell surface), allowing connections between the solar cells to be made towards the creation of a module.

The top surface 205 of the ARC layer 210 has two regions or portions 206 and 208. A metallized region 206 is the portion of the top surface 205 formed by, for example, a fire-through paste. A non-metallized region 208 is the portion of top surface 205 that is not formed by fire-through paste or other metallic material. Thus, non-metallized region 208 may be, for example a dielectric ARC, amorphous silicon, or a TCO. A metallic article 245, such as a copper electroformed piece, that is configured to serve as an electrical conduit (e.g., a bus bar, grid line or finger) has a bottom surface 270 that is coupled to at least part of both the metallized region 206 and the non-metallized region 208, as indicated by the dashed lines “a”, “b” and “c”, by using an active solder (not shown). The active solder can be applied, for example, to the bottom surface 270 of the metallic article 245, either continuously along the length of bottom surface 270, or at discrete points. Alternatively, the active solder can be applied to top surface 205 of the semiconductor 202. Use of an active solder to join metallic article 245 to non-metallized region 208, such as at point “b”, provides an increased mechanical bond between metallic article 245 and semiconductor 202 compared to bonding only at the metallic regions 206 (points “a” and “c”).

In other embodiments, the metallic article 245 may be oriented perpendicularly to what is shown in FIG. 2, and may be bonded along the length of metallized regions 206 (e.g., fire-through paste), or may be bonded parallel to metallized region 206 but on exposed coating 208. In yet, further embodiments, metallized regions 206 may not, exist on semiconductor 202, such as on a TCO type of solar cell. In such TCO cells, the top surface 205 would consist only of a non-metallized region 208, to which metallic article 245 would be joined using active solder.

Because the metallic article 245 can have a height-to-width aspect ratio that is greater than aspect ratios of conventional metallic articles, the metallic article 245 may have less surface area at a contact surface (e.g., a surface facing the semiconductor). For example, in conventional solar cell attachment, a bus bar is soldered to tabbing wire with standard solders with a relatively larger contact area, the contact area being defined by, for example, a bus bar of 1.5-2 mm wide×the length of the solar cell. When using a metallic article with smaller contact interfaces, a contact area between the metallic article and the fire-through paste can be defined by the length of the solar cell×the lesser of i) the width of the fire-through paste or ii) the metallic article. For example, the width of the fire-through paste may be approximately 60 microns. The width of the metallic article may range from, for example, about 10 microns to 5 mm. Thus, disclosed embodiments provide for methods of attaching the metallic article 245 so as to increase the strength of a joint between the metallic article 245 and the photo voltaic cell, while keeping the dimensions of the metallic article 245 as small as possible to minimize shading.

Furthermore, conventional soldering joins only metal to metal. In the embodiment of FIG. 2, the use of an active solder enables metallic article 245 to be joined not only to the metal paste of conductive layer 204 but also to the non-metallized region 208 of ARC layer 210. ARC layer 210 may be, for example, a silicon nitride, which is typically very difficult to bond to metal. In other embodiments, coating layer 210 may be an amorphous silicon, a transparent conductive oxide, or a dielectric layer. Thus, the mechanical bond between metallic article 245 to the photovoltaic cell is improved by being joined at multiple areas along its length—including non-metallized regions 208—rather than just being soldered to the conductive, metallized areas 206. The metallic article 245 can be soldered to region 208 of the wafer between the fire-through paste, for example, directly on the top surface of the semiconductor material and/or the ARC layer, thereby increasing the total bond strength of the metallic article 245 to the wafer by increasing the joint area. Such a joint between metallic article and non-metallized region 208 of the wafer 202 is made possible by using active solders for attachment.

In other embodiments, ultrasonically soldering can be employed to even further strengthen the intermetallic joint. In either case (i.e., active solder with or without ultrasonic soldering), the need to use a flux is eliminated. The ultrasonic soldering technique according to embodiments also provides additional strength in bonding. For example, ultrasonic soldering with an active solder enables attaching the metallic article to the wafer when the junction or top surface of the wafer includes a difficult-to-attach film such as a heterojunction with intrinsic thin layer (HIT), other standard photovoltaic semiconductor materials, and/or ARC layer including, for example, silicon nitride or a transparent conductive oxide (TCO).

Embodiments using active solder and/or ultrasonic soldering are described below with particular steps in sequence. Steps known to the skilled artisan are not described in further detail.

As a first step according to an embodiment, the metallic article can be coated with the active solder. For a bonding process, the solder amount can be tuned and controlled in accordance with the following considerations. Using ultrasonic energy requires a medium to transmit the ultrasonic waves efficiently from the ultrasonic source (e.g., the soldering tip) to the bonding interface. Thus, all materials in a path of the ultrasonic waves should be able to transfer energy with minimal damping. For example, air is an undesirable material because air dampens the ultrasonic waves drastically thus rendering them ineffective for removing oxide and for bonding. Therefore, reducing or minimizing the amount of air between the soldering tip and the bonding interface is preferable to ensure effective ultrasonic soldering. Thus, it may be advantageous to have more of the metallic article's surface area covered with the solder (e.g., having solder on more than one side), because molten materials are generally a superior medium for transferring ultrasonic energy as compared to solids and gases.

Conversely, the sonication process may cause solder splash, an undesired effect due to shading of the photovoltaic cell. To minimize solder splash caused by movement generated by the sonication process, it is desirable to reduce or minimize the amount of solder coating used. Thus, it may be advantageous to have less of the metallic article's surface area covered with the solder (e.g., having solder on only one side), because additional solder can cause solder splash.

With the foregoing considerations for proper solder amount, there is a trade-off between ensuring that the ultrasonic energy is not dampened and reducing splashing. Depending on the process used for the coating step, the solder can be coated on only the side of the metallic article that is attached to the substrate layer or the solder can be coated on more than one side, for example, all sides. Various processes for the coating step shall now be described in more detail.

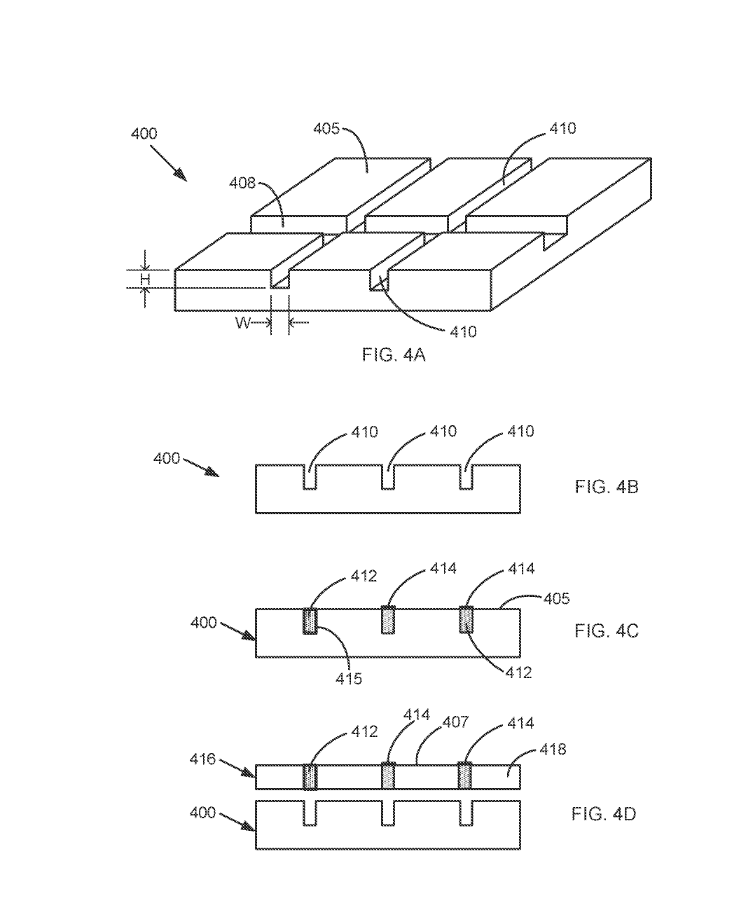

FIG. 4A is a perspective view of electroplating in conjunction with a mandrel 400 according to an embodiment. In some embodiments, the mandrel 400 may be used to both form the metallic article and coat the article with active solder. In other embodiments, the metallic article may be formed by other methods, and be placed in mandrel 400 for application of the active solder. The mandrel 400 may be made of electrically conductive material such stainless steel, copper, anodized aluminum, titanium, or molybdenum, nickel, nickel-iron alloy (e.g., invar), copper, or any combinations of these metals, and may be designed with sufficient area to allow for high plating currents and enable high throughput. In other embodiments, mandrel 400 may be made with, for example, a stack of an electrically conductive material and a dielectric material, or with two electrically conductive materials. The mandrel 400 has an outer surface 405 with a preformed pattern that includes pattern elements 408 and 410 and can be customized for a desired shape of the metallic article/electrical conduit element to be produced. In this embodiment, the pattern elements 408 and 410 are grooves or trenches with a rectangular cross-section, although in other embodiments, the pattern elements 408 and 410 may have other cross-sectional shapes, such as triangle, diamond, rhombus, trapezoid, and other regular or irregular polygons. The pattern elements 408 and 410 are depicted as intersecting segments to form a grid-type pattern, in which sets of parallel lines intersect perpendicularly to each other in this embodiment.

The pattern elements 410 have a height ‘H’ and width ‘W’, where the height-to-width ratio defines an aspect ratio. By using the pattern elements 408 and 410 in the mandrel 400 to form a metallic article, the electroformed metallic parts can be tailored for photovoltaic applications. For example, the aspect ratio may be between about 0.01 and about 10. In some embodiments, the aspect ratio can be designed to be greater than 1, such as between about 1 and about 10, or between about 1 and about 5. Having a height greater than the width allows the metal layer to carry enough current but reduce the shading on the cell compared to, for example, standard circular wires which have an aspect ratio of 1, or compared to conventional screen-printed patterns which are horizontally flat and have aspect ratios less than 1. Shading values for screen-printed metal fingers may be, for example, over 6%. Thus, the ability to produce electrical conduits with aspect ratios greater than 1 enable minimal aperture loss to a photovoltaic cell, which is important to maximizing efficiency. In embodiments where the electroformed electrical conduit is used on a back surface of a solar cell, aspect ratios of other values, such as less than 1, may be used.

The aspect ratio, as well as the cross-sectional shape and longitudinal layout of the pattern elements, may be electroformed to meet desired specifications such as electrical current capacity, series resistance, shading losses, and cell layout. Any electroforming process can be used. For example, a metallic article produced within mandrel 400 may be formed by an electroplating process. In particular, because electroplating is generally an isotropic process, confining the electroplating with a pattern mandrel to customize the shape of the parts is a significant improvement for maximizing efficiency. Furthermore, although tail yet narrow conduit lines typically would tend to be unstable when placing them on a semiconductor surface, the customized patterns that may be produced through the use of a mandrel allows for features such as interconnecting lines to provide stability for these tall but narrow conduits. In some embodiments, for example, the preformed patterns may be configured as a continuous grid with intersecting lines. This configuration not only provides mechanical stability to the plurality of electroformed elements that form the grid, but also enables a low series resistance since the current is spread over more conduits. A grid-type structure can also increase the robustness of a cell. For example, if some portion of the grid becomes broken or non-functional, the electrical current can flow around the broken area due to the presence of the grid pattern.

FIGS. 4B-4D are simplified cross-sectional views of exemplary stages in producing a metal layer piece using mandrel 400.

In FIG. 4B, the mandrel 400 with pattern elements 410 is provided. The mandrel 400 is subjected to an electroforming process, in which electroformed elements 412 are formed within the pattern elements 410 as shown in FIG. 4C. The electroformed elements 412 may be, for example, copper only, or in other embodiments, alloys of copper. In other embodiments, a layer of nickel may be plated onto the mandrel 400 first, followed by copper so that the nickel provides a barrier against copper contamination of a finished semiconductor device. An additional nickel layer may optionally be plated over the top of the electroformed elements 412 to encapsulate the copper, as depicted by layer 415 in FIG. 4C. In other embodiments, multiple layers may be plated within the pattern elements 410, using various metals as desired to achieve the necessary properties of the metallic article to be produced.

In some embodiments, an active solder may be applied to the metallic article during the electroforming process. For example, in FIG. 4C an active solder layer 414 may be electroplated after the element 412 has been formed within mandrel 400 and remains in the mandrel 400, thus covering one face of the element 412. The active solder layer 414 would join the electroformed element 412 (e.g. bottom surface 270 of FIG. 2) to a photovoltaic cell or other semiconductor. The presence of active solder on the single side—the top surface—is sufficient for attachment. In another embodiment, the active solder may be electroplated to cover multiple sides of the electroformed element 412, such as after the electroformed element 412 has been removed from mandrel 400. In such an embodiment, coating layer 415 in FIG. 4C would represent active solder covering multiple surfaces of the electroformed element 412.

In yet other embodiments not shown, a metallic article may have additional metallic portions such as a bus bar that are formed on top of the surface 405, in addition to those that are formed within the preformed patterns 410. An active solder layer may be plated on those additional surfaces as well.

In FIG. 4D, the electroformed elements 452 are removed from the mandrel 400 as a free-standing metallic article 416. The electroformed elements 412 may include intersecting elements 418, such as would be formed by patterns 408 of FIG. 4A. The intersecting elements 418 may assist in making the metallic article 416 a unitary, free-standing piece such that it may be easily transferred to other processing steps while keeping the individual elements 412 and 418 aligned with each other. The top surface 407 of metallic article 416 would be joined to a photo voltaic cell, with active solder 414 (or 415 if covering multiple surfaces) as the bonding agent.

Alternatively, the electroplating step may be completed after the metallic article 416 has been removed from the mandrel 400, in which case the solder is coated on more than one side of the metallic article 416. Having solder on more sides can improve the efficiency of ultrasonic soldering by providing a better medium for ultrasonic energy transfer to the metallic article 416 during attachment.

In another embodiment, active solder may be applied to the metallic article using hot air solder leveling (HASL) in conjunction with a mandrel. In the HASL process, the solder is applied to the metallic article while the metallic article is still supported in the mandrel, such as in FIG. 4C, thus enabling the solder to be coated only on one side of the metallic article. The mandrel, with the metallic article in it, is immersed into a HASL bath such that the active solder is coated onto the exposed surface of the metallic article. In some embodiments, the HASL process is performed in an inert atmosphere, such as nitrogen.

Active solder may also be applied to the metallic article by solder paste transfer according to an embodiment. The solder paste transfer can be performed using an inking process, where a solder paste can be first printed on a surface and the metallic article is then brought into contact with the printed surface to transfer some of the paste onto the metallic article. This process also enables the solder to be coated only on one side of the metallic article.

As a second step according to an embodiment, components can be preheated to various desired temperatures to improve soldering conditions. The components can be preheated using, for example, a hot gun, infra-red heat, hot plate, or microwave, but the components can be preheated using any known preheating process. The wafer/substrate layer and the metallic article can be preheated to temperatures within about 20-35° C., such as within 25° C., of a melting point of the active solder. The specific preheat temperature will depend on the overall thermal insulation and other characteristics of the soldering set-up. A soldering horn can also be preheated to temperatures that are higher than the melting point of the active solder, for example, within about 20-35° C., such as within 25° C. higher than the melting point of the active solder. The soldering horn can also be configured to apply heat to the metallic article.

The melting point of the solder varies depending on the solder composition. For example, for a relatively higher temperature solder, one possible solder composition with a solder temperature of approximately 220 C includes a max of 94 wt % tin, 4 wt % silver, 2.4 wt % titanium, 0.1 wt % cerium, and 0.1 wt % gallium. For a relatively lower temperature solder with a solder temperature of approximately 140 C, another possible solder composition includes about 50-55 wt % bismuth, 40-45 wt % tin, 1.5-2.8 wt % silver, 1.8-2.8 wt % titanium, 0-0.2 wt % gallium and/or cerium, and 0-0.1 wt % iron, copper, and/or nickel. In other embodiments, the active solder composition may be: a) 60-70 wt % tin, 3-6 wt % antimony, 3-5 wt % zinc, and 25-35 wt % indium, with a melting point of approximately 155 C; b) 70-80 wt % tin, 3-5 wt % antimony, 3-5 wt % zinc, and 15-25 wt % indium, with a melting point of approximately 182 C; or c) 94-96 wt % tin, 3-5 wt % antimony, and 1-3 wt % zinc, with a melting point of approximately 217 C.

As a third step according to an embodiment, ultrasonic energy is used to break surface oxides that conventionally are removed only by using a flux, or other chemical means.

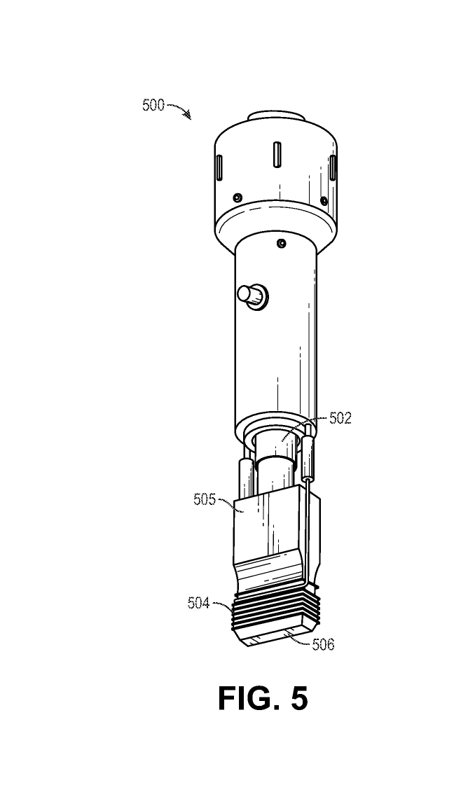

FIG. 5 is a perspective view of an ultrasonic soldering tool 500 according to an embodiment. The ultrasonic soldering tool uses an ultrasonic transducer 502, for example, a piezoelectric transducer that converts electrical energy into ultrasound, with an ultrasonic horn 505. A temperature sensor and heater 504 can sense the current temperature of the soldering tip 506 and heat the tip 506 to a desired temperature in accordance with the solder used. The soldering tip 506 can be selected and/or customized to have attributes that will achieve the desired effects of strength and/or reliability in forming the intermetallic joints.

With respect to size, in conventional ultrasonic soldering, soldering iron tips of the dimension from 1 mm×1 mm to 4 mm×4 mm are used for point soldering. In embodiments, the soldering tip 506 is selected or customized to enable bonding large areas of the metallic article to a wafer/substrate layer, which can reduce manufacturing time. Tips as large as the wafer size (e.g., 156 mm×156 mm) can be used, thus enabling single-pass bonding by continuously moving the soldering tool 500 along the metallic article. If the metallic article includes a grid-like pattern as described in FIG. 3B, a soldering tip can be selected to have a width that is the same as a width of one element of the grid-like pattern, such as an elongated element or finger 310/320, or bus bar 245 of FIG. 2, The soldering tool 500 would then be moved along each element to solder that element. In another embodiment, a soldering tip can be selected to have a width that is the same as the width of the entire grid. For example, the soldering tool may have a width approximately the width of metal layer 300b of FIG. 3B, thereby enabling bonding of the entire grid in a single pass. Alternatively, a width of the soldering tip can be selected to be smaller than the width of the entire grid, for example, ¼ or ½ of the width of grid 300b. Soldering of the grid can be then achieved with multiple passes of the soldering tool, such as by moving it along lengthwise along a portion of the grid, and then making another pass along an adjacent portion, and repeating this until the entire grid has been heated and soldered.

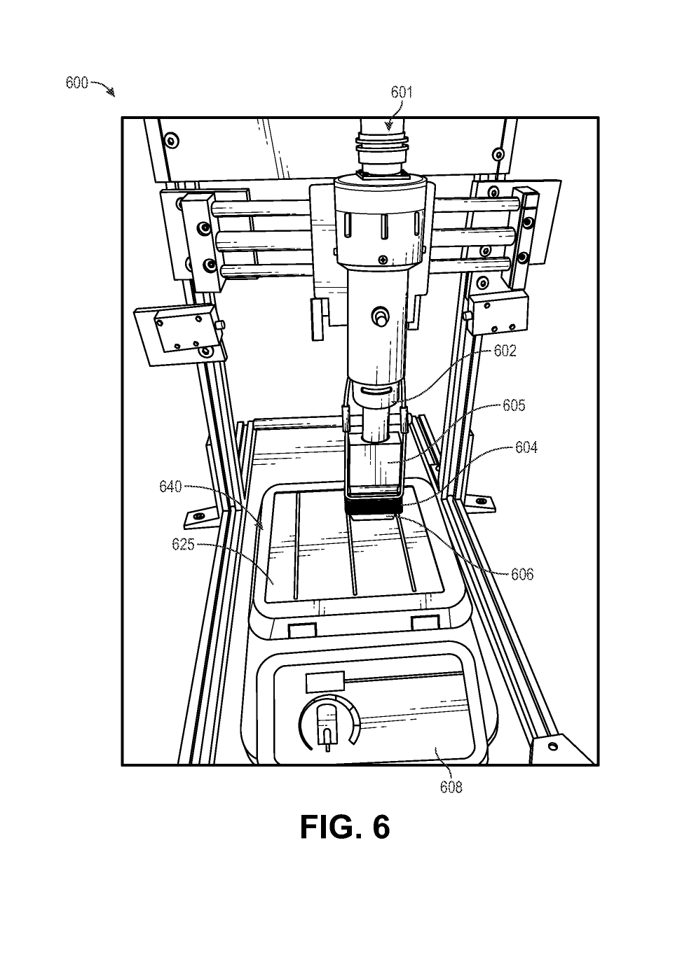

With respect to shape and design, the soldering tip 506 can be selected or customized to have the required power and frequency to meet the strength and/or reliability specification(s), as discussed in more detail with reference to FIG. 6.

FIG. 6 is a perspective view of an ultrasonic soldering setup 600 according to an embodiment. In the ultrasonic soldering setup 600, an ultrasonic soldering tool 601 includes an ultrasonic transducer 602, an ultrasonic horn 605, a temperature sensor and heater 604, and a soldering tip 606. A wafer 640 is preheated using a preheating device 608, so that surface 625 is heated. Preheating device 608 may be, for example, a hot plate in this embodiment, or a hot gun, infra-red heat, or microwave. A metallic article, which may be separately preheated or not, is placed on top of the wafer, and the ultrasonic soldering tool 601 can be moved continuously along the top surface of the assembly to bond the metallic article to the wafer.

The horn frequency and temperature can be tuned and controlled. A horn frequency can be inversely proportional to a size of the horn such that larger contact areas can require horns with lower frequencies than smaller contact areas. The horn frequency can be between 20 kHz and 60 kHz, such as between 20-50 kHz, or such as approximately 30 kHz frequency. A horn temperature can be varied to improve cavitation performance, thereby more effectively enabling the ultrasonic energy to be transferred to the solder and remove the native oxides.

A horn larger than those used in point soldering, such as a wide area horn, can be used to account for the relatively larger number of contact points for the metallic article on the top surface of the wafer. A wide area horn can be moved along the partial or entire length or width of the wafer to cover the entire wafer area, thereby helping to ensure that the temperature profile before, during, and after bonding is consistent across the whole wafer. The wide area horn can also be moved along the partial or entire length or width of the metallic article.

After the active solder is applied and/or ultrasonic soldering is complete, the bonded joint can be cooled. Preferably, this is done quickly to prevent the solder from moving to adjacent regions of the intended bond areas, thus minimizing the joint strength and increasing undesired shading. Thus, preferably, the bonded joint is cooled to a temperature below the melting point of the solder quickly. For example, immediately after bonding one region (even while the soldering horn is continuously moving to another region), the bonded region can be cooled, such as with a forced gas that is applied using an air knife or air gun.

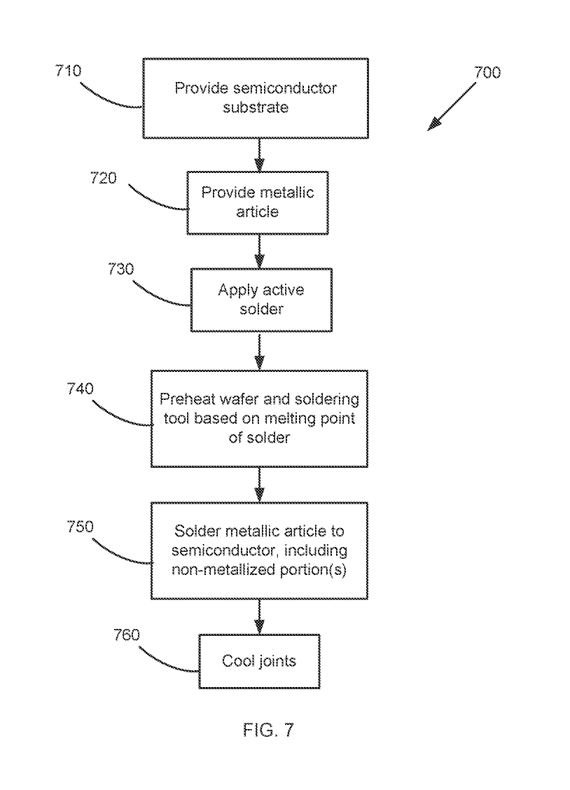

FIG. 7 is a flow diagram of an exemplary active solder method 700 according to an embodiment. In step 710 a semiconductor substrate having a coating is provided, and in step 720 a metallic article is provided. The coating may be a dielectric ARC such as silicon nitride, a conductive ARC such as a TCO, or an amorphous silicon. In some embodiments, the semiconductor also includes a conductive coating, such as a silver fire-through paste, at regions to which electrical contact with a metallic article is to be joined. The conductive coating thus defines metallized regions (where the conductive layer is applied) and non-metallized regions (where the conductive layer is not applied) on the wafer. In other embodiments, no conductive coating is used, such that the top surface of the semiconductor is completely non-metallized. The metallic article may be an electroformed element as described in relation to FIGS. 3A-3C, or an otherwise-formed electrical conduit. Then an active solder is applied at step 730, for example, by coating the metallic article or portions of the top surface of the semiconductor substrate and/or ARC layer with the active solder. If applying the active solder to the metallic article, one or more sides of the metallic article may be covered with active solder. Steps 710-730 can be performed in any order or simultaneously. In step 740, the wafer and soldering tool are preheated based on the melting point of the solder. In some embodiments, the metallic article may also be preheated. The metallic article is then placed on the semiconductor substrate and soldered to the wafer in step 750, such as by moving the soldering tool along a portion of or all of the metallic article. The soldering in step 750 may involve soldering to only a non-metallized portion of the semiconductor, or to both metallized and non-metallized portions. Use of an active solder reduces or eliminates the need for a flux in step 750. The joints are cooled at step 760 and the process ends.

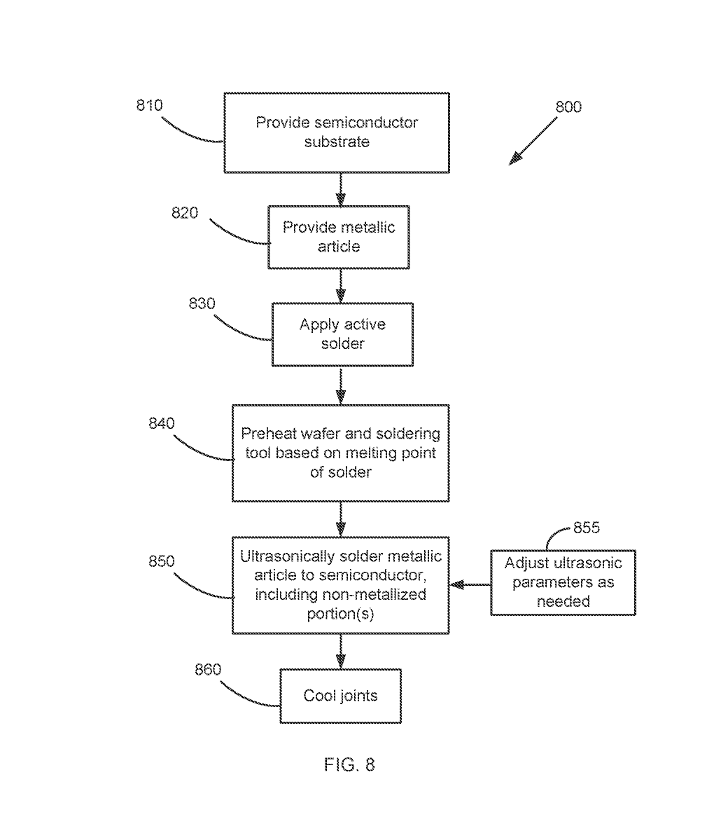

FIG. 8 is a flow diagram of an exemplary ultrasonic soldering process 800 according to an embodiment. The process starts with providing a wafer with semiconductor substrate, including a coating layer, at step 810, and providing a metallic article at step 820. The coating layer may have metallized conductive regions similar to that described in relation to step 710 of FIG. 7, thus defining metallized regions (where the conductive layer is applied) and exposed regions (where the conductive layer is not applied) on the wafer. Alternatively, the semiconductor may comprise only a non-metallized surface, such as a TCO cell without conductive regions formed by silver fire-through paste. Then, active solder is applied in step 830 to areas in which the metallic article will be soldered to the semiconductor. The active solder may be applied to the semiconductor, or to the metallic article. If applied to the metallic article, active solder may be coated only on the bottom surface that is to be bonded to the semiconductor, or may be coated on multiple surfaces of the metallic article. As shown, steps 810-830 can be performed in any order or simultaneously. After steps 810-830 are complete, the wafer and soldering tool, and optionally the metallic article, are preheated at step 840 based on the melting point of the solder. The metallic article is ultrasonically soldered—to both metallized and non-metallized regions of the wafer, or alternatively to just non-metallized regions—at predetermined joints in step 850, typically without the use of a flux. In step 855, the soldering tip size, temperature and frequency are selected, customized, and/or adjusted based on specification and factors described above. These soldering parameters can be selected and/or customized prior to the start of the process 800, and adjusted at any step of the process, e.g., during the soldering step 850. In some embodiments, an ultrasonic horn may be applied at discrete locations, for example, intersections of a grid-like pattern of the metallic article and/or intersections of the metallic article with silver paste fingers and portions of the semiconductor substrate, anti-reflective coating, and/or amorphous silicon between the silver paste fingers. In other embodiments, the ultrasonic horn may be moved continuously along portions of the metallic article. The joints are then cooled in step 860, such as with ambient air or forced air, and the process ends.

In eliminating the need for a flux, described embodiments carry multiple advantages. For example, the metallic article and photovoltaic cell may experience decrease risk of corrosion, and may better preserve electrical and chemical properties of the components. Unsightly residues may also be decreased, along with reduction of process costs associated with applying and cleaning of residual.

Although the embodiments herein have primarily been described with respect to photovoltaic applications, the processes and devices may also be applied to other semiconductor applications such as redistribution layers (RDL's) or flex circuits. Furthermore, the flow chart steps may be performed in alternate sequences, and may include additional steps not shown. For example, as described above, soldered joints can be cooled while other joints are being soldered.

While the specification has been described in detail with respect to specific embodiments of the invention, it will be appreciated that those skilled in the art, upon attaining an understanding of the foregoing, may readily conceive of alterations to, variations of, and equivalents to these embodiments.

These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only, and is not intended to limit the invention.

What is claimed is:

1. A method of coupling a metallic article to a photovoltaic cell, the method comprising:
providing a metallic article that is configured to serve as an electrical conduit within the photovoltaic cell, the metallic article having a first surface;
providing a semiconductor substrate that includes a coating at a top surface of the semiconductor substrate, wherein the coating is a dielectric anti-reflective coating, a transparent conductive oxide or an amorphous silicon; and
coupling the metallic article to the top surface of the semiconductor substrate, the coupling including soldering the first surface of the metallic article to the top surface of the semiconductor substrate using an active solder.

2. The method of claim 1, wherein the top surface of the semiconductor substrate comprises a metallized portion of the coating and a non-metallized portion of the coating, and wherein the metallic article is soldered to both the metallized and non-metallized portions.

3. The method of claim 2 wherein the metallized portion comprises a silver fire-through paste.

4. The method of claim 1, wherein the step of coupling the metallic article to the top surface of the semiconductor substrate comprises:
preheating the semiconductor substrate to a predetermined temperature based on a melting point of the active solder;
preheating a soldering tool to a soldering temperature that is greater than or equal to the melting point of the active solder;
placing the metallic article onto the top surface of the semiconductor substrate;
using the soldering tool to apply heat to the metallic article; and
cooling the metallic article to a temperature that is below the melting point of the active solder, after the metallic article is coupled to the top surface.

5. The method of claim 4, wherein the predetermined temperature is within about 20-35° C. less than the melting point of the active solder; and
wherein the soldering temperature is within about 20-35° C. higher than the melting point of the active solder.

6. The method of claim 4, wherein the cooling includes applying a forced gas.

7. The method of claim 1, wherein the metallic article comprises copper.

8. The method of claim 7, wherein the metallic article has a nickel coating on the copper.

9. The method of claim 1, wherein the metallic article includes an elongated element having an aspect ratio greater than 1, the aspect ratio being a ratio of a height of the elongated element to a width of the elongated element.

10. The method of claim 1, wherein a contact area between the metallic article and the second portion has a width less than or equal to approximately 60 microns.

11. The method of claim 1, wherein the soldering is performed in the absence of a flux.

12. The method of claim 1, wherein the active solder includes at least one of tin, silver, titanium, cerium, gallium, bismuth, iron, copper, nickel, antimony, zinc and indium.

13. The method of claim 1, wherein the dielectric anti-reflective coating is a silicon nitride.

14. The method of claim 1, wherein the soldering includes continuously moving a soldering tool along the metallic article.

15. The method of claim 1, further comprising:
electroplating the active solder onto the first surface of the metallic article while the metallic article is secured within a mandrel.

16. The method of claim 1, further comprising:
electroplating the active solder onto multiple sides of the metallic article, including the first surface.

17. The method of claim 1, further comprising coating the active solder onto the first surface of the metallic article using a molten solder wet dip coating method or a hot air solder leveling method.

18. The method of claim 1, further comprising coating the active solder onto the first surface of the metallic article by printing a solder paste on a printing surface and then bringing the printing surface into contact with the first surface of the metallic grid.

19. The method of claim 1, wherein the soldering includes varying a soldering temperature of a soldering tool within a predetermined range to remove residual oxide.

20. The method of claim 1, wherein a soldering tool and the metallic article have substantially the same width at an interface between the metallic article and the metallized portion.

21. The method of claim 1 wherein the metallic article is configured as a free-standing grid.

22. The method of claim 1 wherein the metallic article is an electroformed article.

23. The method of claim 1 wherein the soldering comprises ultrasonic soldering with a soldering tool, and wherein the soldering tool comprises a soldering horn.

24. The method of claim 23, wherein the metallic article has a first surface coated with an active solder;

25. The method of claim 23, further comprising selecting a frequency of a soldering horn based at least on a size of the soldering horn.

26. The method of claim 25, wherein the frequency is between 20 kHz and 60 kHz.

27. The method of claim 23, wherein the ultrasonic soldering includes selecting a soldering temperature of the soldering tool within a predetermined range to improve effectiveness of ultrasonic energy.

28. The method of claim 23, wherein a width of a soldering horn is substantially the same as a width of the metallic article at an interface between the metallic article and the semiconductor substrate.
